(19) United States
(12) Patent Application Publication
(10) Pub. No.: US 2015/0243490 A1
(43) Pub. Date: Aug. 27, 2015

(54) SUBSTRATE PROCESSING APPARATUS AND SUBSTRATE PROCESSING METHOD

(71) Applicant: WONIK IPS CO., LTD., Pyeongtaek-Si (KR)

(72) Inventors: Dong Ho RYU, Namyangju-Si (KR); Kyung Eun LEE, Yangju-Si (KR); Tae Ho HAM, Pyeongtaek-Si (KR); Yong Jin KIM, Anseong-Si (KR)

(21) Appl. No.: 14/633,123

(22) Filed: Feb. 26, 2015

(30) Foreign Application Priority Data
Feb. 27, 2014 (KR) 10-2014-0023493

(51) Int. Cl. H01J 37/32

(52) U.S. Cl. CPC H01J 37/32899; H01J 37/32743

(57) ABSTRACT

The present invention relates to a substrate processing apparatus and a substrate processing method, the substrate processing apparatus including: a load-lock chamber; a transfer chamber disposed on one side of the load-lock chamber; a process chamber disposed on one side of the transfer chamber; and a substrate transfer robot disposed inside the transfer chamber to transfer a substrate between the load-lock chamber and the process chamber, wherein the process chamber includes a plurality of substrate support plates configured to support the substrate, a plurality of gas spray units configured to respectively spray process gases on the plurality of substrate support plates, a turntable configured to transfer the substrate between the plurality of substrate support plates, a first gate through which an unprocessed substrate is taken in, and a second gate through which a processed substrate is taken out; and the substrate transfer robot independently transfers the unprocessed substrate and the processed substrate through the first gate and the second gate, thereby improving substrate processing efficiency.

### CROSS-REFERENCE TO RELATED APPLICATION

This application claims priority to Korean Patent Application No. 10-2014-0023493 filed on Feb. 27, 2014 and all the benefits accruing therefrom under 35 U.S.C. §119, the contents of which are incorporated by reference in their entirety.

### BACKGROUND

The present disclosure relates to a substrate processing apparatus and a substrate processing method, and more particularly, to a substrate processing apparatus and substrate processing method capable of improving substrate processing efficiency.

Generally, a cluster system indicates a multi-chamber apparatus including a substrate transfer robot (or a handler) and a plurality of processing modules provided around the substrate transfer robot. Recently, there is a high demand for the cluster system for consistently performing a plurality of processing processes in an apparatus for manufacturing a liquid crystal display device (LCD), a plasma display device, a semiconductor or the like.

Such a multi-chamber apparatus includes a load-lock chamber for loading/unloading a substrate from/to the outside, a transfer chamber communicated with the load-lock chamber, and to which the substrate is transferred, and a process chamber communicated with the transfer chamber, and in which the substrate is substantially processed. Also, the transfer chamber is provided with a substrate transfer robot transferring the substrate.

A plurality of substrates are processed in the multi process chamber of the aforementioned multi-chamber apparatus, typically, by using the same process gas. Therefore, in order to process the substrate by using a different process gas, it is necessary to purge an inside of the process chamber, so that the time required to process the substrate is increased, and thus productivity is decreased.

### PRIOR ART DOCUMENT

### Patent Document

(Patent Document 1) KR 2013-57409A

### SUMMARY

The present disclosure provides a substrate processing apparatus and a substrate processing method in which substrates are processed in a process chamber by using different process gases, thereby improving processing efficiency.

The present disclosure also provides a substrate processing apparatus and a substrate processing method in which a plurality of substrates may be efficiently loaded and unloaded in and from a process chamber.

In accordance with an exemplary embodiment, a substrate processing apparatus includes: a load-lock chamber; a transfer chamber disposed on one side of the load-lock chamber; a process chamber disposed on one side of the transfer chamber; and a substrate transfer robot disposed inside the transfer chamber to transfer a substrate between the load-lock chamber and the process chamber, wherein the process chamber comprises a plurality of substrate support plates configured to support the substrate, a plurality of gas spray units configured to respectively spray process gases on the plurality of substrate support plates, a turntable configured to transfer the substrate between the plurality of substrate support plates, a first gate through which an unprocessed substrate is taken in, and a second gate through which a processed substrate is taken out; and the substrate transfer robot independently transfers the unprocessed substrate and the processed substrate through the first gate and the second gate.

The process chamber may include a main body having an opened upper portion and an inner space formed therein; and a top lid provided on the main body to cover the upper portion of the main body, wherein the top lid has an extension portion which extends upward and downward to form therein a space in which the substrate is processed.

The space in which the substrate is processed may be provided in plurality in the top lid; and the gas spray unit and the substrate support plate may be provided in number corresponding to the number of the spaces in which the substrate is processed.

At least one of the plurality of the gas spray units may spray a process gas different from process gases sprayed from the remaining gas spray units.

A plurality of substrate support rings configured to support the substrates may bee provided on the turntable; a plurality of openings through which the substrate support plates are elevated, may be formed in the turntable, and a protrusion may be provided inside each of the openings so as to support the substrate support rings; and the substrate support rings may be selectively supported by the substrate support plate and the turntable.

The substrate transfer robot may include: a rotation shaft disposed in the transfer chamber; a loading arm rotatably connected to an upper portion of the rotation shaft to transfer the unprocessed substrate to the process chamber through the first gate; and an unloading arm rotatably connected to the rotation shaft to unload the processed substrate in the process chamber through the second gate.

The load-lock chamber may include: a first load-lock chamber configured to accommodate the unprocessed substrate; and a second load-lock chamber configured to accommodate the processed substrate in the process chamber.

In accordance with another exemplary embodiment, a substrate processing method uses a substrate processing apparatus that includes a load-lock chamber, a transfer chamber disposed on one side of the load-lock chamber, a process chamber disposed on one side of the transfer chamber, and a substrate transfer robot disposed in the transfer chamber, wherein the process chamber is provided with a first gate through which an unprocessed substrate is taken in and a second gate through which a processed substrate is taken out; and the substrate transfer robot takes the unprocessed substrate into the process chamber through the first gate, and takes the processed substrate in the process chamber out through the second gate.

The process chamber may include a plurality of substrate, a plurality of gas spray units disposed so as to face the plurality of the substrate support plates, a turntable configured to transfer a substrate between the plurality of substrate support plates, and a plurality of substrate processing spaces respectively formed between the plurality of substrate support plates and the plurality of gas spray units, wherein when any one of the plurality of substrates has been processed in any one of the plurality of the substrate processing spaces, the processed substrate is transferred to another one of the substrate support plates by the rotation of the turntable such that the plurality of substrates are processed in the plurality of substrate processing spaces different from each other.

A loading region may be provided in a side of the first gate of the process chamber, and an unloading region may be provided in a side of the second gate; any one of the plurality of substrate support plates may be provided in each of the loading region and the unloading region to form a substrate processing space; and a substrate processing may be started in the substrate processing space of the loading region, and be completed in the substrate processing space of the unloading region.

The same process gas may be supplied to all the plurality of gas spray units to perform the same substrate processing in all the plurality of substrate processing spaces.

A different process gas may be supplied to at least one of the plurality of gas spray units to perform a different substrate processing in at least one of the plurality of substrate processing spaces.

Different substrate processing processes may be performed between the substrate processing space provided in the loading region and the substrate processing space provided in the unloading region.

A plasma processing with respect to the substrate may be performed in at least one of the plurality of substrate processing spaces.

### BRIEF DESCRIPTION OF THE DRAWINGS

Exemplary embodiments can be understood in more detail from the following description taken in conjunction with the accompanying drawings, in which:

FIG. 1 is a schematic plan view illustrating a substrate processing apparatus in accordance with an exemplary embodiment;

FIG. 2 is a cross-sectional view illustrating an inner structure of a process chamber illustrated in FIG. 1;

FIG. 3 is a perspective view illustrating a substrate transfer robot illustrated in FIG. 1;

FIG. 4 is a side view illustrating a substrate transfer robot illustrated in FIG. 1;

FIG. 5 shows processes of taking a substrate out a load-lock chamber through a substrate transferring method in accordance with an exemplary embodiment;

FIGS. 6 to 12 are views illustrating processes of loading and unloading a substrate through a substrate transferring method in accordance with an exemplary embodiment; and

FIGS. 13 to 15 are views conceptually illustrating various methods of processing a substrate in a process chamber in accordance with an exemplary embodiment.

### DETAILED DESCRIPTION OF EMBODIMENTS

Hereinafter, specific embodiments will be described in detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art.

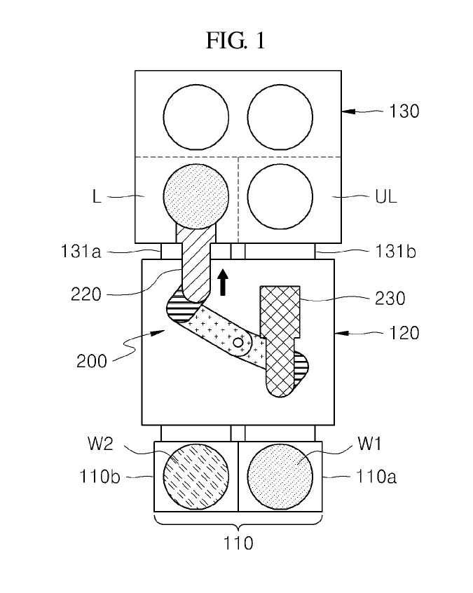

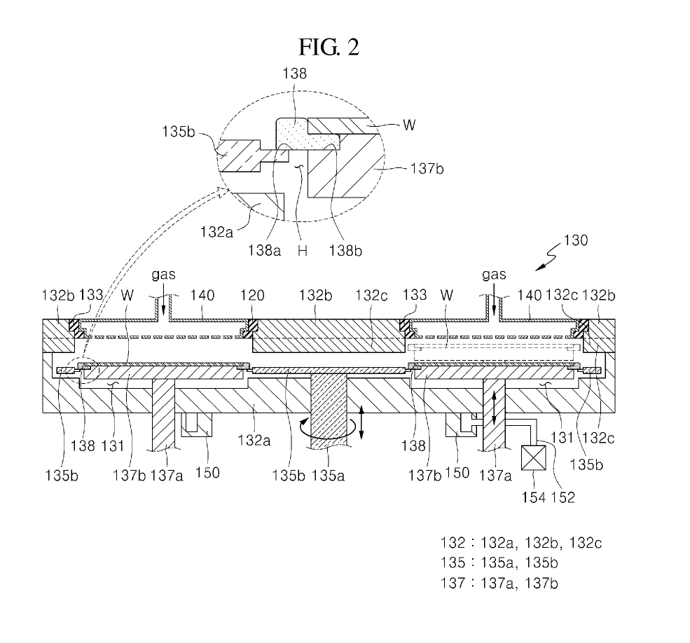

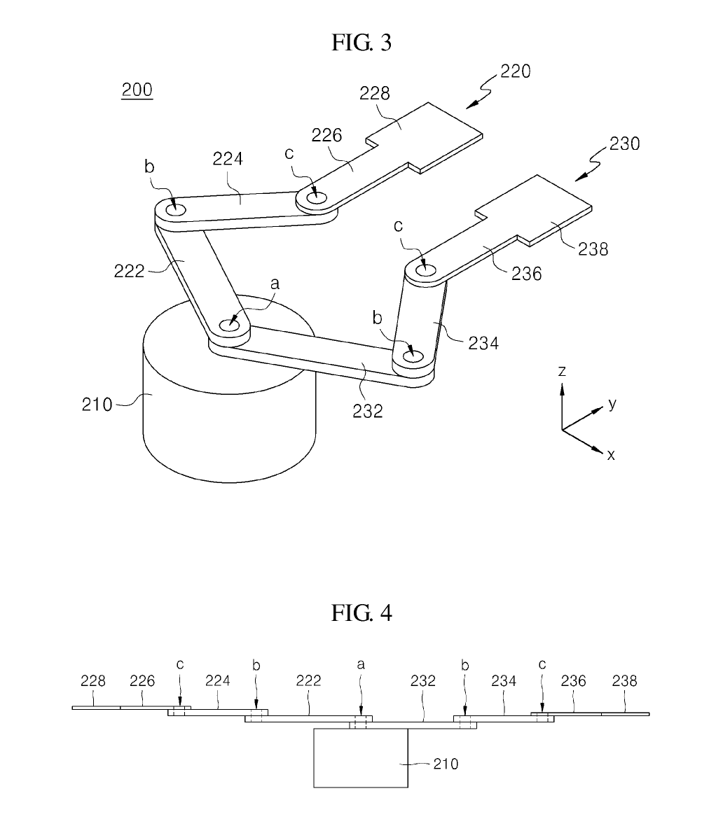

FIG. 1 is a schematic plan view illustrating a substrate processing apparatus in accordance with an exemplary embodiment, FIG. 2 is a cross-sectional view illustrating an inner structure of a process chamber illustrated in FIG. 1, FIG. 3 is a perspective view illustrating a substrate transfer robot illustrated in FIG. 1, and FIG. 4 is a side view illustrating a substrate transfer robot illustrated in FIG. 1.

Referring to FIG. 1, a substrate processing apparatus includes a cassette module (not shown), an atmospheric module (not shown), a load-lock chamber 110, a transfer chamber 120, and a process chamber 130. A cassette accommodating substrates to be processed is loaded in the cassette module, or a cassette accommodating processed substrates is unloaded therefrom. The atmospheric module is provided in the rear of the cassette module, and a conveyance robot (not shown) operable under the atmosphere is disposed inside the atmospheric module. The conveyance robot takes a substrate accommodated in the cassette in the load-lock chamber 110, or takes a substrate in the load-lock chamber 110 out to the cassette. Also, the load-lock chamber 110 is provided between the atmospheric module and the transfer chamber 120, and is a buffer space in which a substrate taken in from the outside or taken out to the outside temporarily stays. When the substrate is taken from the outside while the load-lock chamber 110 maintains an atmospheric state, the load-lock chamber 110 is made into a vacuum state, and when the substrate is taken out to the outside, the load-lock chamber 110 is changed from the vacuum state to the atmospheric state. At this time, the load-lock chamber 110 may include a first load-lock chamber 110a accommodating an unprocessed substrate W1, and a second load-lock chamber 110b accommodating a processed substrate W2 in which a processing such as depositing, or etching is completed in the process chamber 130. In addition, the first load-lock chamber 110a and the second load-lock chamber 110b may be provided in parallel such that inner spaces thereof accommodating substrates are separated from each other. Also, the first load-lock chamber 110a and the second load-lock chamber 110b may be separately provided with a gate through which a substrate is taken in or out.

The transfer chamber 120 is provided between the load-lock chamber 110 and the process chamber 130, and a substrate transfer robot 200 operable in a vacuum state is rotatably disposed therein. The substrate transfer robot 200 transfers the substrates W1 and W2 to the load lock-chamber 110 and the process chamber 130.

In the process chamber 130, a variety of multiple-processing such as depositing and etching are performed with respect to the unprocessed substrate W1 taken therein.

Typically, the process chambers 130 are radially disposed with the transfer chamber 120 in-between, or symmetrically disposed with the transfer chamber 120 in-between. In addition, at least one substrate may be loaded in the process chamber 130, and especially, when a plurality of substrates are loaded, the plurality of substrates are processed on the loaded position. However, in an exemplarily embodiment, a plurality of substrates, for example, four substrates may be loaded in the process chamber 130, and each of the plurality of substrates may be transferred from a loaded region to a different region.

The process chamber 130 is provided with a main body 132a having an opened upper portion, and a top lid 132b disposed on the main body 132a so as to be openable. When the top lid 132b is coupled to the upper portion of the main body 132a to close an inside of the main body 132a, a closed space is formed such that a processing, such as a deposition process with respect to a substrate is performed in the process chamber 130. Since the space is generally formed in a vacuum atmosphere, a discharge pipe 150 for discharging a gas existing in the space is connected to a predetermined portion of the process chamber 130, for example, a bottom surface or a side surface, and the discharge pipe 150 is connected to a vacuum pump 152. Also, gates 131a and 131b for taking a substrate in the space or out to the outside of the space may be formed on a side wall of the main body 132a. The gates 131a and 131b are formed on a side wall of the main body 132a adjacent to the transfer chamber 120, and may include a first gate 131a for taking the substrate in the process chamber 130 and a second gate 131b for taking the substrate out to the outside of the process chamber 130.

As illustrated in FIG. 2, a substrate processing space in which a substrate is processed may be formed under the top lid 132b That is, the top lid 132b may include an extension portion 132c extending downward along edge thereof. Accordingly, the substrate processing space, which is defined by a recess (not shown) having a predetermined height, may be formed under the top lid 132b. The aforementioned substrate processing space may be formed in plurality under the top lid 132b, and for example, may be formed in number corresponding to the number of substrate supports plate disposed in the process chamber 130. The extension portion 132c may be formed on an edge as well as a central portion of the top lid 132b, and may be formed so as to connect the edge and central portion of the top lid 132b. A plane of the substrate processing space may be formed in the same shape as the substrate, and be formed in a square shape or a fan shape according to a shape of the process chamber 130. The substrate processing space formed in the aforementioned shape is formed on the upper side of a substrate support unit 137 described later, and thus allows an independent processing for each substrate to be performed. Also, in order to perfectly separate the substrate processing space, a nozzle (not shown) spraying a curtain gas may be formed on the extension portion 132c of the top-lid 132b. The nozzle may be formed so as to spray the curtain gas along an edge of a substrate, and be formed so as to spray the spray gas on a region except for a region on which the substrate is disposed.

A gas spray unit 140 spraying a process gas on a substrate support plate described later may be provided on the top lid 132b. The gas spray unit 140 may be formed in number corresponding to the number of the substrate support plates, and at least one gas spray unit 140 may be connected to a gas storage unit supplying different gases. The gas spray unit 140 may be provided in the gas processing space formed under the aforementioned top lid 132b.

Also, a substrate support unit 137 on which the substrate is disposed in processing the substrate, may be provided in the process chamber 130. The substrate support unit 137 includes a support shaft 137a that penetrates a bottom surface of the main body 132a and is disposed upward and downward, and a substrate support plate 137b that is connected to an upper portion of the support shaft 137a. The substrate support unit 137 may be in plurality, for example, four in the process chamber 130. At this time, the support shafts 127a respectively constituting the substrate support units 137 may be spaced a predetermined interval apart from each other with respect to a center of the process chamber 130, and be radially disposed. Further, the substrate support plate 137b is a plate-type having a predetermined thickness, has the similar shape as the substrate, and for example, may be formed in a disc shape. The substrate support plate 137b is connected to an upper portion of the support shaft 137a in an intersecting direction (that is, an orthogonal direction) with respect to a longitudinal direction of the support shaft 137a, and the substrate support plates 137b are formed so as to be separated from each other. Also, a substrate support plate positioning recess 131 recessed at a predetermined depth may be formed on a bottom surface of the process chamber 130 on which the substrate support unit 137 is provided. The substrate support plate positioning recess 131 may be formed in the similar shape as the substrate support plate 137b, and be formed at a depth in which the substrate support plate 137 is movable upward and downward. A space formed in the process chamber 130 may be decreased through the aforementioned configuration, thereby reducing an amount of a process gas supplied inside the process chamber 130, and reducing the time required for purging an inside of the process chamber 130. Also, a first stepped portion 138b, which has a step lower than a top surface of the substrate support plate 137b, may be formed on an edge of the substrate support plate 137b. The first stepped portion 138b functions to position a substrate support ring 138 described later. A heating member may be provided in the substrate support plate 137b, and a separate heating device may be provided on a lower portion of the substrate support plate 137b according to the need. The substrate support shaft 137a penetrates the bottom surface of the process chamber 130, and is connected to an outer driving means such as a motor to elevate the substrate support plate 137b.

Also, a lift pin (not shown) may be provided to the substrate support unit 137, and may be exposed from a top surface of the substrate support plate 137b by upward and downward movement of the substrate support plate 137b portion to support the substrate. At this time, since a loading and an unloading of the substrate are respectively preformed in a loading region L and an unloading region UL, the lift pin may be provided in the loading region L and the unloading region UL.

Meanwhile, a loading region L in which an unprocessed substrate W1 is loaded in the process chamber 130, and an unloading region UL in which a processed substrate W2 in the process chamber 130 is unloaded to the outside may be formed in the process chamber 130. The loading region L means a region in which a substrate support unit 137 of a plurality of substrate support units 137 adjacent to the first gate 131a is disposed. In addition, the unloading region UL means a region in which a substrate support unit 137 of the plurality of substrate support units 137 adjacent to the second gate 131b is disposed. Herein, the first gate 131a is described that the unprocessed substrate W1 is transferred therethrough, and the second gate 131b is described that the processed substrate W2 is transferred therethough, but functions thereof may be changed according to the need. As described above, since the loading region L and the unloading region UL are defined in the process chamber 130, in order to treat a plurality of substrates, the substrate may be transferred from an inside of the process chamber 130 to a relevant region. Accordingly, a substrate transfer unit 135 may be provided to the process chamber 130. The substrate transfer unit 135 may include a turntable 135b and a rotation shaft 135a rotating the turntable 135b. The rotation shaft 135a penetrates a bottom surface of a central portion of the process chamber 130, that is, the main body 132a and is disposed upward and downward, and a turntable 135b is connected to an upper portion of the rotation shaft 135a. The rotation shaft 135a is rotatable and is movable upward and downward to rotate and move the turntable 135b upward and downward. The turntable 135b is a plate-type having a predetermined thickness, and for example, four openings H may be formed so as to correspond to the number of the substrate support plate 137b provided in the process chamber 130. The opening H is formed so as to have a diameter greater than that of the substrate support plate 137b, and thus the substrate support plate 137b may be moved upward and downward through the opening H. A second stepped portion 138a, which has a step lower than a top surface of the turntable 135b, may be formed along an edge of the opening H. The second stepped portion 138a may be formed at the same height as the first stepped portion 138b formed on the substrate support plate 137b. Here, it is described that the second stepped portion 138a is continuously formed along an edge of the opening H, but the second stepped portion 138a may be discontinuously formed, and in other words, a protrusion partially protruding along the edge of the opening H may be formed to support the substrate support ring 138.

Through the aforementioned configuration, when the substrate is processed, the substrate may be disposed on the substrate support plate 137b, and when the substrate is transferred to the loading region L and the unloading region UL in order to load and unload the substrate, the substrate may be disposed on the turntable 135b. However, since the opening H of the turntable 135b is formed so as to have a diameter greater than that of the substrate support plate 137b and the substrate, it is impossible to stably dispose the substrate on the turntable 135b when the substrate is transferred. Accordingly, a substrate support ring 138, which may be selectively supported by an edge of the substrate support plate 137b and the turntable 135b, may be provided. The substrate support ring 138 may be provided so as to be supported by the first stepped portion 138a (or a protrusion) and a second stepped portion 138b, and when a top surface of the substrate support plate 137b and a top surface of the turntable 135b match each other, a top surface of the substrate support ring 138 may be disposed on the same plane as the top surfaces of the substrate support plate 137b and the turntable 135b. When the rotation shaft 137a is elevated in order to process the substrate, the substrate is stably disposed on the substrate support ring 138 and the substrate support plate 137b, and when the rotation shaft 137a is descended in order to transfer the substrate, the substrate is supported by the substrate support ring 138 to be stably disposed on the turntable 135b. At this time, the substrate support ring 138 may be formed of the same material or a material having the similar heat conductivity as the substrate support plate 137b in order to maintain temperature throughout the substrate in processing the substrate.

Since the substrate transfer robot 200 provided in the transfer chamber 120 is manufactured in a multi-joint structure, the substrate transfer robot 120 may stably transfer the substrate in the relatively small transfer chamber 120. The substrate transfer robot 200 may be formed in various shape, but herein, it will be described the substrate transfer robot 200 including a loading arm 200 that loads an unprocessed substrate W1 in the process chamber 130, and an unloading arm 200 that unloads a processed substrate W2 in the process chamber 130.

Referring to FIGS. 3 and 4, the substrate transfer robot 200 includes a driving unit (not shown) that supplies rotation force, a rotation shaft 210 that rotates a body of the substrate transfer robot 200 according to an operation of the driving unit, a loading arm 220 that is connected to an upper portion of the rotation shaft 210, an unloading arm 230 connected to an upper portion of the loading arm 220, and a controller that controls an operation of the rotation shaft 210, the loading arm 220, and the unloading arm 230. At this time, the loading arm 220 may be used in loading an unprocessed substrate W1 accommodated in the load-lock chamber 110 in the process chamber 130, and the unloading arm 230 may be used in unloading a processed substrate in the process chamber 130 to the load-lock chamber. The loading arm 220 includes a first arm 222 of which one side is rotatably connected to a center of an upper portion of the rotation shaft 210, a second arm 224 of which one side is rotatably connected to the other side of the first arm 222, a hand portion 226 of which one side is rotatably connected to the other side of the second arm 224. At this time, a connection portion of the rotation shaft 210 and the first arm 222 is referred to as a first joint portion a, a connection portion of the first arm 222 and the second arm 224 is referred to as a second joint portion b, and a connection portion of the second arm 224 and the hand portion 226 is referred to as a third joint portion c. In addition, each of the joint portions is formed so as to rotate at an angle of 360° or less. The loading arm 220 and the unloading arm 230 may be formed in the same structure. Also, the unloading arm 230 may be formed in the same structure as the loading arm 220, and is different from the loading arm 220 in that the first arm 232 thereof is connected to one side of the rotation shaft 210 through one side of the upper portion of the first arm 222 of the loading arm 220.

The rotation shaft 210 rotates the first arms 222 and 232, the second arms 224 and 234, and the hand portions 226 and 236 according to an operation of the driving unit, and is formed so as to be moved along a Z-axis, that is, upward and downward.

Each of the first arms 222 and 232, and the second arms 224 and 234 rotates through the connection portion, and thus may be adjusted in direction and length. At this time, the first arms 222 and 232 rotate with respect to the first joint portion a in the transfer chamber 120 to provide straight-line motion in an Y-axis, the second arms 224 and 234 rotate with respect to the second joint portion b to provide straight-line motion in an X-axis.

Also, the hand portions 226 and 236 support the substrate by using blades 228 and 238 formed on ends thereof, and are connected to ends of the second arms 224 and 234 through the third joint portion c and rotate with respect to the third joint portion c.

Further, the first arms 222 and 232 of the loading arm 220 and the unloading arm 230 may individually rotate with the same rotation radius by using the first joint portion as a concentric point. The substrate transfer robot 200 is characterized in that hands portions 226 and 236 of the loading arm 220 and the unloading arm 230 may be arranged in parallel so as to be directed to the same direction when the substrate is taken in or out from the load-lock chamber 110 or the process chamber 130 in order to load or unload the substrate. Therefore, the loading arm 220 and the unloading arm 230 may allow the substrate to be smoothly transferred in the relatively small transfer chamber 120. The driving unit independently rotates the rotation shaft 210, each of the first arms 222 and 232, each of the second arms 224 and 234, and each of the hand portions 226 and 236 to provide straight-line motion. The driving unit may be disposed inside or outside the transfer chamber 120.

The controller controls operations of the driving unit, the rotation shaft 210, the first arms 222 and 232, the second arms 224 and 234, and the hand portions 226 and 236. The controller controls an operation of the driving unit according to a preset manual to control a rotation direction of the first arms 222 and 232, the second arms 224 and 234, and the hand portions 226 and 236, and thus allows the substrate to be loaded or unloaded.

A substrate transferring method using the substrate processing apparatus will be described below.

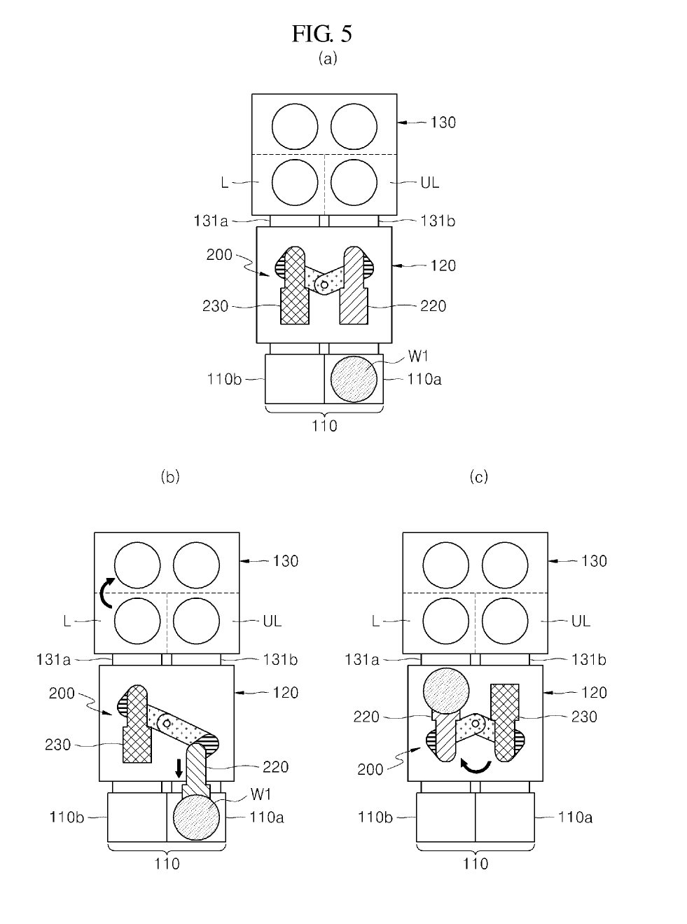

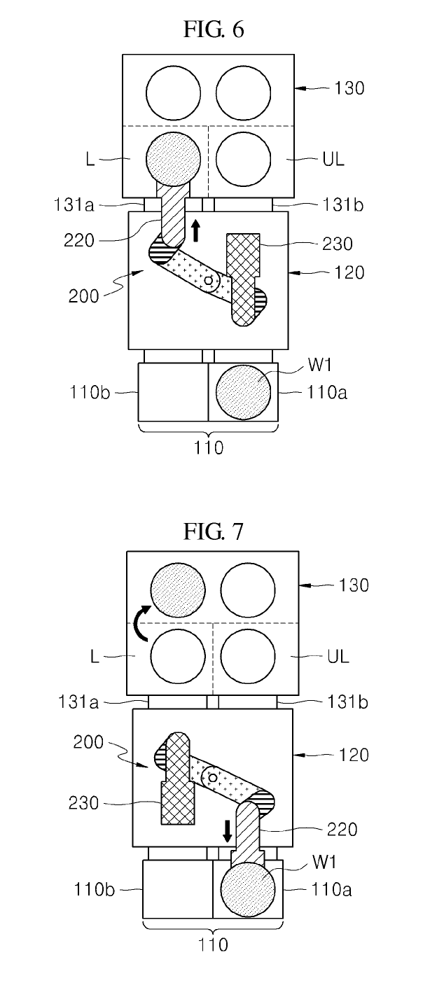

FIG. 5 shows processes of taking a substrate out from a load-lock chamber through a substrate transferring method in accordance with an exemplary embodiment; FIGS. 6 to 12 are views illustrating processes of loading and unloading a substrate through a substrate transferring method in accordance with an exemplary embodiment; and FIGS. 13 to 15 are views conceptually illustrating various methods of processing a substrate in a process chamber in accordance with an exemplary embodiment.

The substrate transferring method according to an exemplary includes taking an unprocessed substrate W1 out from the load-lock chamber 110 by using the loading arm 220 of the substrate transfer robot 200 disposed in the transfer chamber 120, loading the taken-out and unprocessed substrate W1 in the process chamber 130, unloading a processed substrate by using the unloading arm 230 when a substrate processing is completed, and taking the processed substrate W2 in the load-lock chamber 110. At this time, the taking of the unprocessed substrate out form the load-lock chamber 110 and the loading of the unprocessed substrate W1 in the process chamber 130 may be repeated by at least times corresponding to the number of the substrate support units 137 disposed in the process chamber 130. In addition, the processing of the substrate loaded in the process chamber 130 may be performed in the way of that the unprocessed substrate W1 is loaded in the process chamber 130, and then a next unprocessed substrate is loaded therein. Also, the unloading of the processed substrate W2 may be repeated by at least times corresponding to the number of the substrate support unit 137 disposed in the process chamber 130. In addition, after the processed substrate is initially unloaded, the unloading of the processed substrate W2 and the loading of the unprocessed substrate W1 may be alternately and repeatedly performed. Hereinafter, forward motion of the hand portions 226 and 236 means a state that the hand portions 226 and 236 are moved to the load-lock chamber 110 or the process chamber 130 in order to take the substrate in or out, and load or unload the substrate, and backward motion of the hand portions 226 and 236 means a state that the hand portions 226 and 236 are moved out of the load-lock chamber 110 or the process chamber 130 in order to take the substrate into or out, and load or unload the substrate. The forward motion or the backward motion of the hand portions 226 and 236 may be adjusted according to an overlap degree between the first arms 222 and 232, and the second arms 224 and 234.

First, processes of taking an unprocessed substrate W1 to be processed, out from the load-lock chamber 110 will be described with reference to FIG. 5.

Referring to FIG. 5, in the substrate transfer robot 200, blades 228 and 238 of the hand portions 226 and 236 are disposed so as to be directed toward the load-lock chamber 110 (see (A) of FIG. 5) in a state that the hand portions 226 and 236 are disposed in parallel. Such a state is referred to as a home position.

After that, the unprocessed substrate W1 is disposed on the blade 228 disposed on an end of the hand portion 226 of the loading arm 220 by moving the hand portion 226 of the loading arm 220 inside a first load-lock chamber 110a of the load-lock chamber 110 accommodating the unprocessed substrate W1 (see (B) of FIG. 5), and then the unprocessed substrate W1 accommodated in the first load-lock chamber 110 a is taken out to the transfer chamber 120 by moving the hand portion 226 backward. When the unprocessed substrate W1 is taken out, the hand portions 226 and 236 of the loading arm 220 and the unloading arm 230 are disposed to be directed toward the process chamber 130 (see (C) of FIG. 5) by rotating the rotation shaft 210 of the substrate transfer robot 200.

Next, when the unprocessed substrate W1 is taken out from the load-lock chamber 110, the unprocessed substrate W1 is loaded in the process chamber 130 (see FIG. 6) by moving the hand portion 226 of the loading arm 220 on which the unprocessed chamber W1 inside the process chamber 130. At this time, the turntable 135b and the substrate support plate 137b are descended by descending the rotation shaft 135a and the support shaft 137a in the process chamber 130, the turntable 135b is disposed at a height lower than that of the substrate support plate 137b, and the lift pin protrudes from a top surface of the substrate support plate 137b. Also, the unprocessed substrate W1 is loaded on the lift pin exposed from the top surface of the substrate support plate 137b of the loading region L by moving the hand portion 226 of the loading arm 220 forward.

When the unprocessed substrate W1 is loaded, the hand portion 226 of the loading arm 220 is moved out of the process chamber 130, and then the first gate 131a is closed. Also, the unprocessed substrate W1 is moved to the substrate processing space under the top lid 132b in a state that the unprocessed substrate W1 is disposed on the substrate support plate 137b and the substrate support ring 138.

When the substrate loaded inside the process chamber 130 is processed, the processed substrate may be moved to an adjacent substrate support plate in order to treat a next substrate. The substrate may be supported by the turntable 135b by disposing the substrate supported by the substrate support plate 137b and the substrate support ring 138 on a first stepped portion 138a of an edge of an opening through the substrate support ring 138. When the substrate is supported by the turntable 135b, the substrate may be moved to a top surface of an adjacent substrate support plate by rotating the rotation shaft 135a by a predetermined degree, for example, 90 degrees. After that, the substrate may be disposed on the substrate support plate 137b through the substrate support ring 138 by descending the rotation shaft 137a.

When the unprocessed substrate W1 is moved to the adjacent support plate, the gas spray unit 140, which is disposed in a region in which the unprocessed substrate W1 is loaded, sprays a process gas to treat the unprocessed substrate W1.

Here, when the unprocessed substrate W1 is moved to the adjacent substrate support plate, the substrate support plate provided in the loading region L of the process chamber 130 is on standby to load a next unprocessed substrate W1.

Next, the next unprocessed substrate W1 is taken out to the first load-lock chamber 110a by repeating the processes illustrated in FIG. 5, and then the loading of the unprocessed substrate W1 into the process chamber 130 and processing processes of the unprocessed substrate W1 are repeated (see FIGS. 6 to 8). The aforementioned processes may be repeated by the number of the substrate support plates 137b or the number of the substrate processing spaces disposed in the process chamber 130. In addition, when through a series of processes, the substrate loaded on the substrate support plate of the loading region L reaches the substrate support plate of the unloading region UL, a substrate processing is completed. At this time, the closing of the first gate 131a and the rotating of the turntable 135b may be performed at the same time as a process of taking the unprocessed substrate W1 out from the first load-lock chamber 110a. While the substrate is processed, the substrate transfer robot 200 is on standby in a state that the unprocessed substrate W1 is disposed on the hand portion 226 of the loading arm 220 in order to taking the unprocessed substrate W1 out from the first load-lock chamber 110a (see (C) of FIG. 5) in order to load the unprocessed substrate W1 in the process chamber 130.

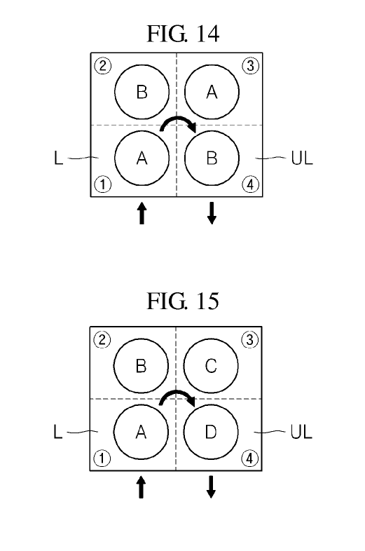

As illustrated in FIG. 13, among a plurality of substrate processing spaces, any one substrate processing space may use a process gas different from that used in the remaining substrate processing spaces to perform the substrate processing. In addition, as illustrated in FIG. 14, two processes using two different process gases may be alternately performed. At this time, two different substrate processing processes may be performed in the loading region and the unloading region, respectively. Also, as illustrated in FIG. 15, substrate processing processes using different process gases may be performed in all of the plurality of substrate processing spaces, and a plasma processing with respect to the substrate may be performed in at least one substrate processing space. For example, a substrate processing process using the same process gas in one process chamber 130 may be depositing the same thin film multiple times step by step when a thin film is deposited. At this time, after depositing the thin film, a plasma processing may be performed in any one of the plurality of substrate processing spaces, for example, a substrate processing space of the unloading region UL. The plasma processing may be performed by applying electric power to the substrate support plate on which the substrate is disposed, and the gas spray unit to form plasma in the substrate processing space, and plasma may be supplied to the substrate processing space through the gas spray unit by exciting the process gas into plasma outside the process chamber 130. Otherwise, the process gas may be supplied to the substrate processing space by exciting the process gas in the gas spray unit.

Also, two different processes using two different process gases may be a process of repeatedly depositing a stacked structure of different thin films, for example, an oxide film and a nitride film. At this time, according to the number of a layer of the stacked structure, even after the substrate reaches the substrate support plate of the unloading region, the thin film may be repeatedly deposited while the substrate is moved by using the turntable.

Also, four different thin films may be deposited in each substrate processing space, and in this case, the plasma processing with respect to the substrate may be also performed in at least one substrate processing space.

The substrate processing may be started in the substrate processing space of the loading region L and be completed in the substrate processing space of the unloading region UL. At this time, even when the number of the substrate processing is greater than that of the substrate processing space, a final substrate processing is completed in the substrate processing space of the unloading region UL, so that the substrate may be taken out.

When the substrate W1 reaches the unloading region UL, and thus the substrate processing is completed, the processed substrate W2 is supported on the lift pin by descending the turntable 135a and the substrate support plate 137b, and protruding the lift pin disposed on the unloading region UL of the process chamber 130 from the top surface of the substrate support plate 137b.

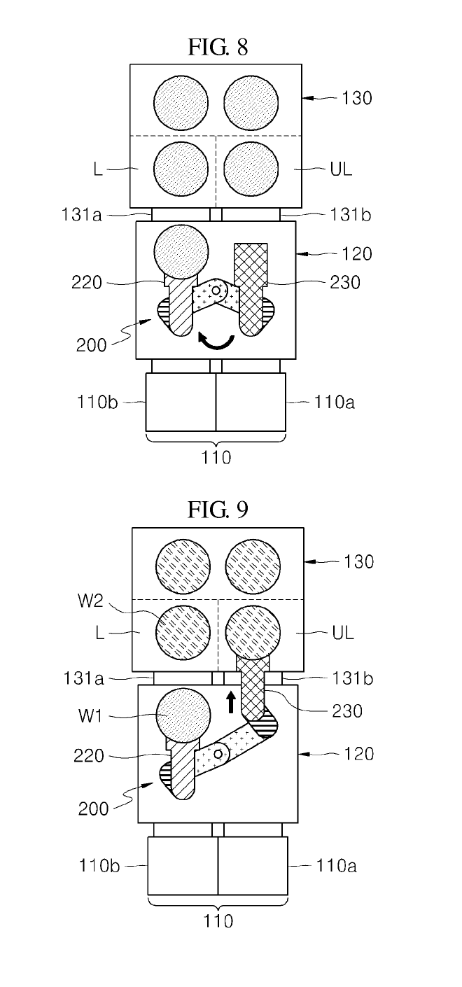

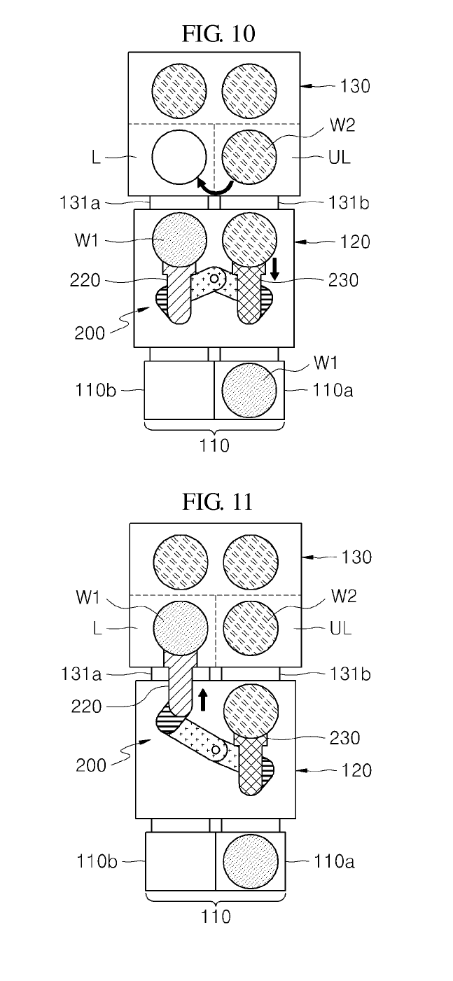

After that, a second gate 131b provided in the unloading region UL is opened, and the hand portion 236 of the unloading arm 230 is moved to the unloading region UL of the process chamber 130 to dispose the processed substrate W2 on the blade 238 of the hand portion 236 (see FIG. 9), and then the hand portion 236 is moved backward to unload the processed substrate W2 inside the transfer chamber 120. When the processed substrate W2 is unloaded, the processed substrate W2 is moved to the loading region L (see FIG. 10) by closing the second gate 131b and rotating the turntable 135b.

Next, the unprocessed substrate W1, which is on standby in the transfer chamber 120, is loaded on the lift pan (see FIG. 11) by opening the first gate 131a, and moving the loading arm 220 inside the process chamber 130.

After that, after the hand portion 226 of the loading arm 220 is moved backward, the first gate 131a is closed, and then the unprocessed substrate W1 is processed in the loading region L. At the same time, hand portions 226 and 236 of the loading arm 220 and the unloading arm 230 are moved to the front of the load-lock chamber 110 by rotating the rotation shaft 210 of the substrate transfer robot 200.

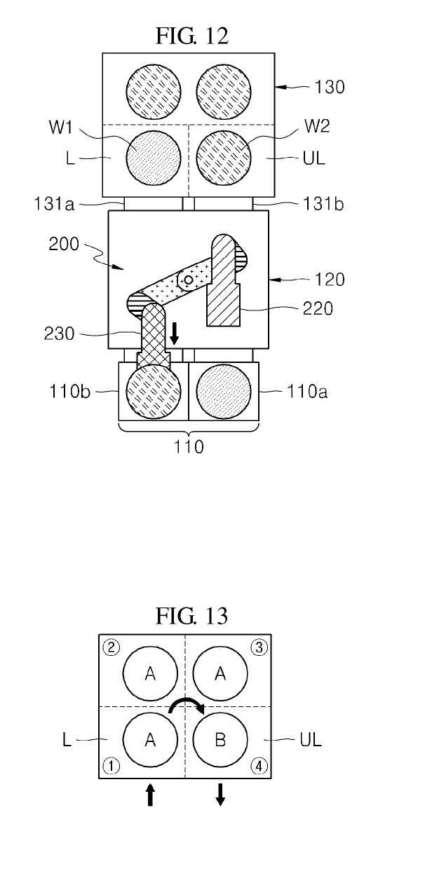

After that, a gate of the second load-lock chamber 110b is opened, and the hand portion 236 of the unloading arm 230 is moved inside the second load-lock chamber 110b to take the processed substrate W2 in the second load-lock chamber 110b (see FIG. 12).

When the processed substrate W2 is taken in the second load-lock chamber 110b, the gate of the second load-lock chamber 110b is closed.

The unloading of the processed substrate W2 and the loading of the unprocessed substrate W1 are repeated in the process chamber 130 by repeating a series of processes.

As described above, in the substrate processing method according to an exemplary embodiment, a plurality of processes may be performed in one process chamber 130, thereby reducing the time required for processing the substrate. Also, the loading arm 220 and the unloading arm 230 of the substrate transfer robot 200 respectively perform a substrate loading and a substrate unloading, thereby reducing the time required for transferring the substrate. Also, although the number of the substrate processed in the process chamber 130a is increased, the substrate may be efficiently transferred without the increment of the number of the substrate transfer robot 200.

In a substrate processing apparatus and a substrate processing method according to an exemplary embodiment, a plurality of substrates may be processed by using different process gases in one process chamber. Therefore, the processing efficiency and the productivity of the substrate may be improved.

Also, the plurality of substrates may be efficiently loaded or unloaded into or from the process chamber. At this time, a loading region and an unloading region of the substrate are defined in the process chamber, and are configured such that the substrate may be transferred to each region, and the substrate is loaded and unloaded through each defined region, thereby reducing the movement number of a substrate transfer robot, and reducing the time required for transferring the substrate.

Although the substrate processing apparatus and substrate processing method have been described with reference to the specific embodiments, they are not limited thereto. Therefore, it will be readily understood by those skilled in the art that various modifications and changes can be made thereto without departing from the spirit and scope of the present invention defined by the appended claims.

1. A substrate processing apparatus comprising:
a load-lock chamber;
a transfer chamber disposed on one side of the load-lock chamber; a process chamber disposed on one side of the transfer chamber; and
a substrate transfer robot disposed inside the transfer chamber to transfer a substrate between the load-lock chamber and the process chamber,
wherein the process chamber comprises a plurality of substrate support plates configured to support the substrate, a plurality of gas spray units configured to respectively spray process gases on the plurality of substrate support plates, a turntable configured to transfer the substrate between the plurality of substrate support plates, a first gate through which an unprocessed substrate is taken in, and a second gate through which a processed substrate is taken out; and
the substrate transfer robot independently transfers the unprocessed substrate and the processed substrate through the first gate and the second gate.

2. The substrate processing apparatus of claim 1, wherein the process chamber comprises:
a main body having an opened upper portion and an inner space formed therein; and
a top lid provided on the main body to cover the upper portion of the main body,
wherein the top lid has an extension portion which extends upward and downward to form therein a space in which the substrate is processed.

3. The substrate processing apparatus of claim 2, wherein the space in which the substrate is processed is provided in plurality in the top lid; and
the gas spray unit and the substrate support plate are provided in number corresponding to the number of the spaces in which the substrate is processed.

4. The substrate processing apparatus of claim 3, wherein at least one of the plurality of the gas spray units sprays a process gas different from process gases sprayed from the remaining gas spray units.

5. The substrate processing apparatus of claim 4, wherein a plurality of substrate support rings configured to support the substrates are provided on the turntable; a plurality of openings through which the substrate support plates are elevated, are formed in the turntable, and a protrusion is provided inside each of the openings so as to support the substrate support rings; and the substrate support rings are selectively supported by the substrate support plate and the turntable.

6. The substrate processing apparatus of claim 1, wherein the substrate transfer robot comprises:
a rotation shaft disposed in the transfer chamber;
a loading arm rotatably connected to an upper portion of the rotation shaft to transfer the unprocessed substrate to the process chamber through the first gate; and
an unloading arm rotatably connected to the rotation shaft to unload the processed substrate in the process chamber through the second gate.

7. The substrate processing apparatus of claim 6, wherein the load-lock chamber comprises:
a first load-lock chamber configured to accommodate the unprocessed substrate; and
a second load-lock chamber configured to accommodate the processed substrate in the process chamber.

8. A substrate processing method using a substrate processing apparatus that comprises a load-lock chamber, a transfer chamber disposed on one side of the load-lock chamber, a process chamber disposed on one side of the transfer chamber, and a substrate transfer robot disposed in the transfer chamber,
wherein the process chamber is provided with a first gate through which an unprocessed substrate is taken in and a second gate through which a processed substrate is taken out; and
the substrate transfer robot takes the unprocessed substrate in the process chamber through the first gate, and takes the processed substrate in the process chamber out through the second gate.

9. The substrate processing method of claim 8, wherein the process chamber comprises a plurality of substrate, a plurality of gas spray units disposed so as to face the plurality of the substrate support plates, a turntable configured to transfer a substrate between the plurality of substrate support plates, and a plurality of substrate processing spaces respectively formed between the plurality of substrate support plates and the plurality of gas spray units,
wherein when any one of the plurality of substrates has been processed in any one of the plurality of the substrate processing spaces, the processed substrate is transferred to another one of the substrate support plates by the rotation of the turntable such that the plurality of substrates are processed in the plurality of substrate processing spaces different from each other.

10. The substrate processing method of claim 9, wherein a loading region is provided in a side of the first gate of the process chamber, and an unloading region is provided in a side of the second gate;
any one of the plurality of substrate support plates is provided in each of the loading region and the unloading region to form a substrate processing space; and
a substrate processing is started in the substrate processing space of the loading region, and is completed in the substrate processing space of the unloading region.

11. The substrate processing method of claim 10, wherein the same process gas is supplied to all the plurality of gas spray units to perform the same substrate processing in all the plurality of substrate processing spaces.

12. The substrate processing method of claim 10, wherein a different process gas is supplied to at least one of the plurality of gas spray units to perform a different substrate processing in at least one of the plurality of substrate processing spaces.

13. The substrate processing method of claim 12, wherein different substrate processing processes are performed between the substrate processing space provided in the loading region and the substrate processing space provided in the unloading region.

14. The substrate processing method of claim 9, wherein a plasma processing with respect to the substrate is performed in at least one of the plurality of substrate processing spaces.
